(19) United States
(12) Patent Application Publication
(10) Pub. No.: US 2026/0033025 A1
(43) Pub. Date: Jan. 29, 2026

(54) IMAGE SENSOR USING METASURFACE LAYER ROUTING

(71) Applicant: Apple Inc., Cupertino, CA (US)

(72) Inventors: Boyang Zhang, San Jose, CA (US); Xiangli Li, Palo Alto, CA (US); Aditya Rayankula, Cupertino, CA (US)

(21) Appl. No.: 19/270,398

(22) Filed: Jul. 15, 2025

Related U.S. Application Data
(60) Provisional application No. 63/675,155, filed on Jul. 24, 2024.

(51) Int. Cl. H10F 39/00; G02B 1/00

(52) U.S. Cl. CPC H10F 39/8053; G02B 1/002; H10F 39/802

(57) ABSTRACT

Systems, apparatuses, and methods for an image sensor using a metasurface routing layer are described. An image capture device includes an array of pixels, a color filter layer disposes over the array of pixels, and a metasurface layer disposed over the color filter layer. The color filter layer includes a first color region over the first pixel for a first color and a second color region over the second pixel for a second color. The metasurface layer includes a first metasurface region to pass light of the first color to the first color region, defining a first effective resolution for the first pixel and a second metasurface region to pass light of the second color to the second color region, defining a second effective resolution for the second pixel larger than the first effective resolution. The second metasurface region at least partially overlaps the first metasurface region.

### CROSS-REFERENCE TO RELATED APPLICATIONS

This application claims the benefit under 35 U.S.C. § 119(e) of U.S. Provisional Patent Application No. 63/675,155, filed Jul. 24, 2024, the contents of which are incorporated herein by reference as if fully disclosed herein.

### TECHNICAL FIELD

The described embodiments relate generally to image capture devices and, more particularly, to systems, apparatuses, and methods for an image sensor using a metasurface routing layer.

### BACKGROUND

Modern consumer electronic devices take many shapes and forms and have numerous uses and functions. Cameras continue to be an important feature of consumer electronics devices. Smartphones, wearables devices, including wrist-worn devices (e.g., watches or fitness tracking devices) and head-mounted devices (e.g., headsets, glasses, or earbuds), and computers (e.g., tablet computers or laptop computers), for example, may use one or more cameras. The imaging capabilities of these consumer electronics devices have steadily increased as individual cameras have improved in quality and devices have started integrating multiple-camera (“multi-camera”) systems and depth sensors. User demand continues for imaging capabilities to capture high quality images in an ever-increasing range of situations. As such, it may be desirable to continue to improve image sensors, including the design of pixels that make up an array of pixels.

Many cameras and other image capture devices include one or more optical components (e.g., a lens or lens assembly) that are configured to focus light, received or reflected from an image, onto the surface of an image sensor. Before or while capturing an image, the distance between the optical component(s) and image sensor (or a tilt or other parameters of the optical components or image sensor) may be adjusted to focus an image onto the image sensor. In some cases, macro (or rough) focusing may be performed for an image sensor prior to capturing an image using the image sensor (e.g., using a macro focus mechanism adjacent the image sensor). Micro (or fine) focusing can then be performed after acquiring one or more images using the image sensor. In other cases, all focusing may be performed prior to capturing an image (e.g., by adjusting one or more relationships between a lens, lens assembly, or image sensor); or all focusing may be performed after acquiring an image (e.g., by adjusting pixel values using one or more digital image processing algorithms). Many cameras and other image capture devices perform focusing operations frequently, and in some cases before and/or after the capture of each image capture frame.

Focusing an image onto an image sensor often entails identifying a perceptible edge between objects, or an edge defined by different colors or brightness (e.g., an edge between dark and light regions), and making adjustments to a lens, lens assembly, image sensor, or pixel value(s) to bring the edge into focus.

### SUMMARY

Described herein are devices and methods for an image sensor using a metasurface routing layer.

Some aspects of this disclosure are directed to an image capture device. The image capture device includes an array of pixels, a color filter layer disposed over the array of pixels, and a metasurface layer disposed over the color filter layer. Each includes a photodetector. The array of pixels includes a first pixel and a second pixel immediately adjacent to the first pixel. The color filter layer includes a first color region positioned over the first pixel and configured to pass light of a first color. The color filter layer further includes a second color region positioned over the second pixel and configured to pass light of a second color. The metasurface layer includes a first metasurface region configured to pass light of the first color to the first color region and thereby define a first effective resolution for the first pixel. The metasurface layer further includes a second metasurface region configured to pass light of the second color to the second color region and thereby define a second effective resolution for the second pixel. The second effective resolution is larger than the first effective resolution. The second metasurface region at least partially overlaps the first metasurface region.

Some aspects of this disclosure are directed to an image capture device. The image capture device includes an array of pixels, a color filter layer disposed over the array of pixels, and a metasurface layer disposed over the color filter layer. The array of pixels includes a first set of pixels and a second set of pixels. The color filter layer includes a first set of color regions corresponding to the first set of pixels and a second set of color regions corresponding to the second set of pixels. The metasurface layer includes a first set of metasurface regions configured to pass light of a first color to the first set of color regions. Each of the first set of metasurface regions defines a first effective resolution for a corresponding pixel of the first set of pixels. The metasurface layer further includes a second set of metasurface regions configured to pass light of a second color to the second set of color regions, each of the second set of metasurface regions defining a second effective resolution for a corresponding pixel of the second set of pixels. The second effective resolution is larger than the first effective resolution. Each metasurface region of the second set of metasurface regions at least partially overlaps a metasurface region of the first set of metasurface regions.

Some aspects of this disclosure are directed to a camera. The camera includes an image capture device, a lens, an actuator, and a processor. The image capture device includes an array of pixels, a color filter layer disposed over the array of pixels, and a metasurface layer disposed over the color filter layer and the array of pixels. The metasurface layer includes a first set of metasurface regions configured to pass light of a first color to a first set of color regions of the color filter, each metasurface region of the first set of metasurface regions defining a first effective resolution for a first set of pixels of the array of pixels. The metasurface layer further includes a second set of metasurface regions configured to pass light of a second color to a second set of color regions of the color filter, each metasurface region of the second set of metasurface regions defining a second effective resolution larger than the first effective resolution, and at least partially overlapping a metasurface region of the first set of metasurface regions. The lens is positioned over the image sensor device and configured to direct light onto the image sensor device. The actuator controls a position of the lens relative to the image sensor device. The processor is configured to acquire an image from the image capture device, determine, based at least in part on the acquired image, a drive signal for the actuator according to an autofocus procedure, and transmit the determined drive signal to the actuator.

In addition to the exemplary aspects and embodiments described above, further aspects and embodiments will become apparent by reference to the drawings and by study of the following description.

### BRIEF DESCRIPTION OF THE DRAWINGS

To easily identify the discussion of any particular element or act, the most significant digit or digits in a reference number refer to the figure number in which that element is first introduced.

FIG. 1A shows a rear view of an illustrative example of a device including an image sensor using a metasurface routing layer as described here. FIG. 1B depicts exemplary components of the device of FIG. 1A.

FIG. 2 shows an example image sensing device, according to certain aspects of the present disclosure.

FIG. 3 shows a cross-section of an example image capture device, according to certain aspects of the present disclosure.

FIG. 4A shows a side view of a pair of pixels, according to certain aspects of the present disclosure.

FIG. 4B shows a top view of an example pair of pixels, according to certain aspects of the present disclosure.

FIG. 4C shows a top view of an example pair of pixels, according to certain aspects of the present disclosure.

FIG. 5A shows a top view of an array of pixels, according to certain aspects of the present disclosure. FIGS. 5B and 5C show cross-sectional side views of an image sensor that includes the array of pixels of FIG. 5A.

FIG. 6 shows a top view of an array of pixels, according to certain aspects of the present disclosure.

FIG. 7 shows a top view of an array of pixels, according to certain aspects of the present disclosure.

FIG. 8A shows a top view of an array of pixels, according to certain aspects of the present disclosure. FIG. 8B shows a cross-sectional side view of an image sensor that includes the array of pixels of FIG. 8A.

FIG. 9 shows a top view of an array of pixels, according to certain aspects of the present disclosure.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The present disclosure relates to image sensors, as well as image capture devices that include these image sensors, that use a metasurface routing layer. A metasurface routing layer may be used to improve the sensitivity of individual pixels of an image sensor. The metasurface routing layer is configured to include a plurality of metasurface regions that includes a metasurface region corresponding to each pixel of an array. Each metasurface region is configured to route light of a particular color to its corresponding pixel. The metasurface regions may be differently sized to provide different effective resolutions for pixels for different colors, which may reduce difference in quantum efficiency (QE) between pixels of different colors. This in turn may simplify white-balancing performed on images captured these image sensors.

In other instances, image sensor pixels of an image capture device may use a microlens, which may be referred to as an on-chip lens (OCL), to focus light incident on an image capture device into a photodiode of the pixel. For example, an array of microlens structures may be formed on a color layer (e.g., a Bayer color filter mosaic) that is in turn formed on an array of image sensor pixels. The use of microlenses in such structures have been shown to improve QE and sensitivity of the pixels.

An image capture device may also utilize phase detection autofocus (PDAF). In some examples, PDAF pixels may be embedded within an image sensor to capture PDAF information. Such PDAF pixels may include a pair of adjacent pixels that are angularly sensitive, for example one pixel being more sensitive to light incident from the left and the other pixel being more sensitive to light incident from the right. For example, left-right sensitive PDAF pixels may be a pair of adjacent pixels under a single microlens. Each pixel may have its own photodiode, and there may be implant isolation or physical trench isolation between the photodiodes of the two pixels. Because of the curvature of the microlens, light from left-incident angles is received mainly by the left-side pixel, and light from right-incident angles is received mainly by the right-side pixel.

The two PDAF pixels will have disparate signals (e.g., signals not matched in magnitude and/or polarity) when an image is not in focus, but will have well-matched signals when an image is in focus. The signals of two PDAF pixels therefore provide PDAF information that can be used by an autofocus (AF) mechanism to adjust the position of one or more optical components (e.g., a lens) or an image sensor, and thereby adjust the focus of an image on the image sensor, or to digitally adjust or compensate for an out-of-focus condition. In some cases, an image may be brought into focus based on a PDAF information obtained during a single image capture frame. By analyzing PDAF information obtained during each image capture frame, images may be quickly and continuously focused on an image sensor.

For an image capture device using a Bayer color filter mosaic, the mosaic of the color filter layer may be selectively modified to provide PDAF pixels within an array that use microlenses to provide left-right selectivity. For example, a typical Bayer color filter mosaic configuration may include a repetitive 2×2 pattern including groups of red pixels and groups of blue pixels along one diagonal, and groups of green pixels along the other diagonal. Such mosaic configuration may be selectively modified to provide two adjacent pixels (e.g., two adjacent red pixels and/or two adjacent blue pixels) as PDAF pixels. In some examples, a 4×4 block of pixels may include a 2×2 block of blue pixels and a 2×2 block of red pixels on one diagonal, and a first 2×2 block of green pixels and a second 2×2 block of green pixels on the other diagonal. The 2×2 block of blue pixels (and/or red pixels) may include a first pair of PDAF pixels under a first microlens and a second pair of PDAF pixel under a second microlens. Each green pixel may have a single associated microlens. The signals of pixels under a shared microlens need to be corrected before being used to generate an image. Such configurations may provide PDAF information based on edges having more than one orientation (e.g., vertical and horizontal edges), to improve PDAF performance (e.g., in low light conditions), to reduce or eliminate the need for signal correction, or to increase the resolution of an image sensor. Additionally, the green pixels may maintain a relatively higher resolution while the blue and/or red pixels provide PDAF functionality. Examples of image capture devices that use microlenses to provide PDAF functionality are discussed in US Patent Publication No. 2023/0090827 (published Mar. 23, 2023), which is incorporated herein by reference in full.

However, further improvements to designs for image capture devices are desired. Described herein are image capture devices that utilize a metasurface routing layer to further improve pixel QE and sensitivity performance over approaches utilizing microlenses. As further described herein, a metasurface layer of an image capture device may be disposed over a color filter layer, which is in turn disposed over an array of pixels. The metasurface layer may also be referred to as a metasurface routing layer. The metasurface layer includes regions that are differently configured for different pixels. Each pixel is associated with a corresponding region of the metasurface layer (also referred to herein as a “metasurface region”) that is configured to direct light to that pixel. The metasurface region for a given pixel may at least partially determine the effective resolution and the angular sensitivity of that pixel. As used herein the “effective resolution” refers to an area from which a pixel may be able to collect light. In the context of the metasurface layer, the effective resolution for a pixel is the light-collecting surface area of the metasurface layer (the corresponding metasurface region) that directs light into the corresponding pixel. The size of the corresponding metasurface region for a pixel defines the effective resolution of a given pixel. As further discussed herein for the describe image capture device, different pixels may have photodiodes with a common area, but may collect light from regions of the metasurface layer having different sizes, and thus different pixel may different effective resolutions.

As used herein, the term “angular sensitivity” of a pixel may refer to the range of angles at which light may be incident on the image sensor and reach the pixel (e.g., the photodiode thereof). As with a microlens, a metasurface may be designed such that light of a certain color, when incident on a predetermined location of the metasurface at a predetermined angle (or range of angles) will be routed to a particular pixel (and thereby be measured by that pixel). Conversely, light incident on the same location at an angle that is different from the predetermined angle (or range of angles) will not be routed to and measured by that pixel (e.g., such light may be filtered out by a different region of the color filter layer). Accordingly, an image sensor may be designed such that certain pixels preferentially receives light incident on the image sensor from certain directions.

The metasurface region for a pixel may be configured to increase the QE for that pixel in some cases. In some embodiments, a first metasurface region for a first pixel is configured to direct light of a first color (e.g., green light) to the first pixel, defining a first effective resolution. A second metasurface region for a second pixel may be configured to direct light of a second color (e.g., blue light or red light) to the second pixel, defining a second effective resolution. The second metasurface region may be configured such that the second effective resolution for the second pixel is larger than the first effective resolution for the first pixel. The first and second metasurface regions may also overlap. For example, a first color light (e.g., green light) may be collected from a region above the first pixel, while a second color light (e.g., blue and/or red light) may be collected from a region above the second pixel as well as at least some of the region above the first pixel.

The metasurface layer of the image capture device may be formed of nanopillars (which may also be referred to as nanopillar structures) that extend through the metasurface layer. In some examples, the nanopillars of the metasurface layer may be formed of a silicon nitride (e.g., SiN) material or titanium oxide (e.g., TiO₂) material, or a combination of these materials. The metasurface layer includes an embedding material different from the material of the nanopillars, such as silicon dioxide (e.g., SiO₂). The nanopillars of the metasurface layer may include one or more different shapes (e.g., geometrical types) of nanopillars, for example round nanopillars, square nanopillars, hexagonal nanopillars, rectangular nanopillars, cross-shaped nanopillars, or a polygon (e.g., square, hexagonal, and so on) nanopillar with a hole extending therethrough. Moreover, for a same shape of nanopillar, different instances of the nanopillar of the metasurface layer may have different dimensions. For example, some square nanopillars may have a first length and width, while other square nanopillars may have a second length and width greater than the first length and width. In some examples, nanopillars of the metasurface layer may have a same height. Stated differently, different nanopillars having the same shape may have different volumes. In other examples, one or more of the nanopillars of the metasurface layer may have a different height. As such, different nanopillars may have a different shape and/or dimensions, but a same volume.

In some examples, the central axes of the nanopillars of the metasurface layer may be arranged in a regular array. In one example, a set of nanopillars in an array (e.g., a set of nine nanopillars in a 3×3 array, a set of sixteen nanopillars in a 4×4 array, a set of twelve nanopillars in a 3×4 array, and so on) may be disposed above each pixel for an image capture device. As discussed, the set of nanopillars may include nanopillars of different shapes, different dimensions, or a combination of nanopillars with both different shapes and dimensions. In other examples, the central axes of the nanopillars of the metasurface layer may be configured other than in a regular array.

The sets of nanopillars above the pixels may be different across the metasurface layer. For example, the sets of nanopillars of the metasurface layer may be configured to form the metasurface regions configured to pass light of different colors as further described herein. As such, depending on the color of light to be passed and the orientation of the metasurface regions, the sets of nanopillars may be differently configured or selected for that metasurface region. For example, the set of nanopillars may be different for metasurface regions associated with passing light of different colors. The set of nanopillars may be further different depending on the orientation of the associated metasurface region.

The image capture devices described herein can achieve similar functionality of a microlens-based image sensor, and also provide additional benefits. In microlens-based image sensors, a given layer of microlenses may include a single microlens at any spatial location along the light-receiving surface, which may limit the light routing capabilities of the microlens layer. Conversely, a metasurface layer may route light differently as a function of wavelength, and thus a given area of the metasurface routing layer (a metasurface region) may act as a first microlens for one wavelength to route light to a first pixel (e.g., as part of a first metasurface region), and may also act as a second microlens (having different focusing properties) for a second wavelength to route light to a second pixel (e.g., as part of a second metasurface region that at least partially overlaps the first metasurface region). Accordingly, the configuration of the various metasurface regions may be selected to provide for different imaging properties for a particular color relative to other colors.

The configuration of metasurface regions of the image sensor devices discussed herein may be chosen to selectively alter the overall sensitivity of certain pixels to account for differences in the QE of these pixels. For example, in microlens based image sensors, green pixels typically have a higher QE than red and blue pixels. In these instances, it may be necessary to change the size of the photodiodes or bin multiple photodiodes together to adjust the differences in QE between different colors. In the present application, red and/or blue pixels may have a different effective resolution than green pixels, which may change the relative sensitivities of these pixels. Specifically, when a pixel receives light from a larger metasurface region, the pixel may collect more photons per unit area of the photodiode as compared to instances in which a pixel receives light from a relatively smaller metasurface region. This will increase the overall sensitivity of the pixel (at the cost of resolution), which effectively increases the QE of that pixel. In this way, the metasurface region may adjust the relative sensitivities of different color pixels without needing to change the size of the photodiodes for these pixels. The metasurface region configurations may therefore reduce or minimize noise that is introduced during white-balancing procedures (e.g., because the QE for the different colors are closer to equal). Moreover, the metasurface routing layer described herein may maintain a resolution and the modulation transfer function (MTF) of the image capture device for the green pixels. In some configurations, the metasurface regions for green pixels may be tuned or otherwise adjusted to be increased as well, such that the QE for green pixels, as well as red and/or blue pixels, are increased. The tradeoff may be decreased resolution and MTF, but an increase in total pixel sensitivity of the image sensor.

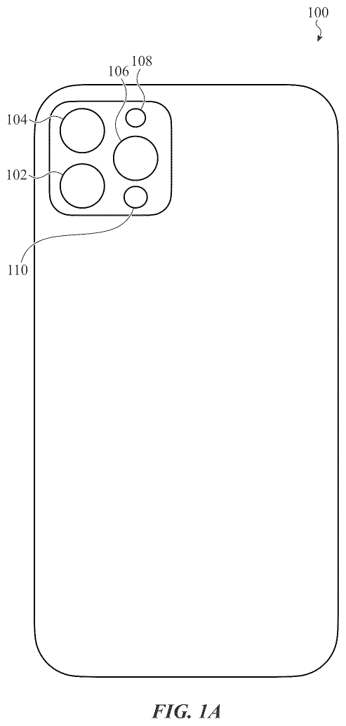

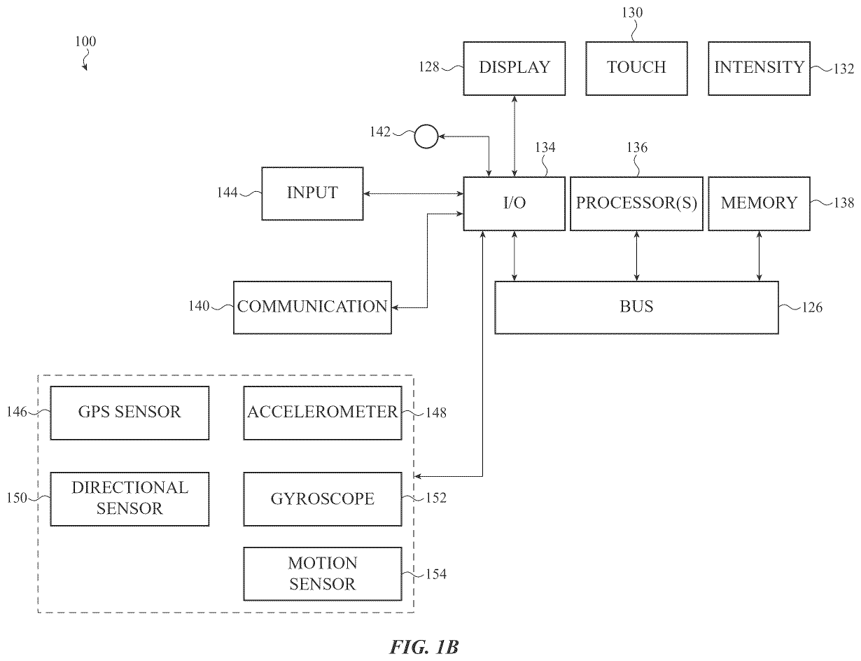

These and other embodiments are discussed below with reference to FIGS. 1A-11. However, those skilled in the art will readily appreciate that the detailed description given herein with respect to these figures is for explanatory purposes only and should not be construed as limiting.

An image sensor using a metasurface routing layer as described herein may be incorporated into a camera module, which in turn may be incorporated into an electronic device such as a phone, tablet, computer, or the like. FIG. 1A depicts an example device 100 as described herein. As shown, the device 100 includes a first camera 102 having an image sensor using a metasurface routing layer.

In some instances, the first camera 102 is part of a multi-camera system. For example, in the variation shown in FIG. 1A, the first camera 102 is part of a multi-camera system having a second camera 104, and a third camera 106. The second camera 104 and/or third camera 106 may also include an image sensor using a metasurface routing layer as described herein, but need not. It should be appreciated that the device 100 may include a single camera, or a multi-camera system having any number of cameras (with any relative positioning) as may be desired. Additionally, while shown as placed on the rear of a device 100, it should be appreciated that a camera having an image sensor using a metasurface routing layer may be additionally or alternatively placed on the front (e.g., a front side having a display) or any other side of the device as desired.

In some instances, the device 100 may include a flash module 108. The flash module 108 may provide illumination to some or all of the fields of view of the cameras of the device 100 (e.g., the fields of view of the first camera 102, the second camera 104, and/or the third camera 106). This may assist with image capture operations in low light settings. Additionally, or alternatively, the device 100 may further include a depth sensor 110 that may calculate depth information for a portion of the environment around the device 100. Specifically, the depth sensor 110 may calculate depth information within a field of coverage (i.e., the widest lateral extent to which the depth sensor is capable of providing depth information). The field of coverage of the depth sensor 110 may at least partially overlap the field of view of one or more of the cameras (e.g., the fields of view of the first camera 102, second camera 104, and/or third camera 106). The depth sensor 110 may be any suitable system that is capable of calculating the distance between the depth sensor 110 and various points in the environment around the device 100.

The depth information may be calculated in any suitable manner. In one non-limiting example, a depth sensor may utilize stereo imaging, in which two images are taken from different positions, and the distance (disparity) between corresponding pixels in the two images may be used to calculate depth information. In another example, a depth sensor may utilize structured light imaging, whereby the depth sensor may image a scene while projecting a known pattern (typically using infrared illumination) toward the scene, and then may look at how the pattern is distorted by the scene to calculate depth information. In still another example, a depth sensor may utilize time of flight sensing, which calculates depth based on the amount of time it takes for light (typically infrared) emitted from the depth sensor to return from the scene. A time-of-flight depth sensor may utilize direct time of flight or indirect time of flight, and may illuminate an entire field of coverage at one time, or may only illuminate a subset of the field of coverage at a given time (e.g., via one or more spots, stripes, or other patterns that may either be fixed or may be scanned across the field of coverage). In instances where a depth sensor utilizes infrared illumination, this infrared illumination may be utilized in a range of ambient conditions without being perceived by a user.

In some embodiments, the device 100 is a portable multifunction electronic device, such as a mobile telephone, that also contains other functions, such as PDA and/or music player functions. Exemplary embodiments of portable multifunction devices include, without limitation, the iPhone®, iPod Touch®, and iPad® devices from Apple Inc. of Cupertino, California. In other embodiments, the device 100 is a head-mounted device, such as an extended reality (XR) device, which may include augmented reality (AR) or virtual reality (VR) devices. Exemplary embodiments of head-mounted devices include, without limitation, the Vision Pro® device from Apple Inc. of Cupertino, California. Other portable electronic devices, such as laptops or tablet computers with touch-sensitive surfaces (e.g., touch screen displays and/or touchpads), are, optionally, used. It should also be understood that, in some embodiments, the device is not a portable communications device, but is a desktop computer, which may have a touch-sensitive surface (e.g., a touch screen display and/or a touchpad). In some embodiments, the electronic device is a computer system that is in communication (e.g., via wireless communication, via wired communication) with a display generation component. The display generation component is configured to provide visual output, such as display via a CRT display, display via an LED display, or display via image projection. In some embodiments, the display generation component is integrated with the computer system. In some embodiments, the display generation component is separate from the computer system. As used herein, “displaying” content includes causing to display the content by transmitting, via a wired or wireless connection, data (e.g., image data or video data) to an integrated or external display generation component to visually produce the content.

FIG. 1B depicts exemplary components of the device 100. In some embodiments, device 100 has a bus 126 that operatively couples an I/O section 134 with one or more computer processors 136 and memory 138. The I/O section 134 can be connected to display 128, which can have touch-sensitive component 130 and, optionally, intensity sensor 132 (e.g., contact intensity sensor). In addition, I/O section 134 can be connected with communication unit 140 for receiving application and operating system data, using Wi-Fi, Bluetooth, near field communication (NFC), cellular, and/or other wireless communication techniques. The device 100 can include input mechanisms 142 and/or 144. Input mechanism 142 is, optionally, a rotatable input device or a depressible and rotatable input device, for example. Input mechanism 142 is, optionally, a button, in some examples. The device 100 optionally includes various sensors, such as GPS sensor 146, accelerometer 148, directional sensor 150 (e.g., compass), gyroscope 152, motion sensor 154, and/or a combination thereof, all of which can be operatively connected to I/O section 134. Some of these sensors, such as accelerometer 148 and gyroscope 152 may assist in determining an orientation of the device 100 or a portion thereof.

Memory 138 of the device 100 can include one or more non-transitory computer-readable storage mediums, for storing computer-executable instructions, which, when executed by one or more computer processors 136, for example, can cause the computer processors to perform the techniques that are described here (such as actuating the mechanical iris assemblies described herein). A computer-readable storage medium can be any medium that can tangibly contain or store computer-executable instructions for use by or in connection with the instruction execution system, apparatus, or device. In some examples, the storage medium is a transitory computer-readable storage medium. In some examples, the storage medium is a non-transitory computer-readable storage medium. The non-transitory computer-readable storage medium can include, but is not limited to, magnetic, optical, and/or semiconductor storages. Examples of such storage include magnetic disks, optical discs based on CD, DVD, or Blu-ray technologies, as well as persistent solid-state memory such as flash, solid-state drives, and the like.

The processor 136 can include, for example, dedicated hardware as defined herein, a computing device as defined herein, a processor, a microprocessor, a programmable logic array (PLA), a programmable array logic (PAL), a generic array logic (GAL), a complex programmable logic device (CPLD), an application-specific integrated circuit (ASIC), a field-programmable gate array (FPGA), or any other programmable logic device (PLD) configurable to execute an operating system and applications of device 100, as well as to facilitate capturing of images as described herein. Device 100 is not limited to the components and configuration of FIG. 1B, but can include other or additional components in multiple configurations.

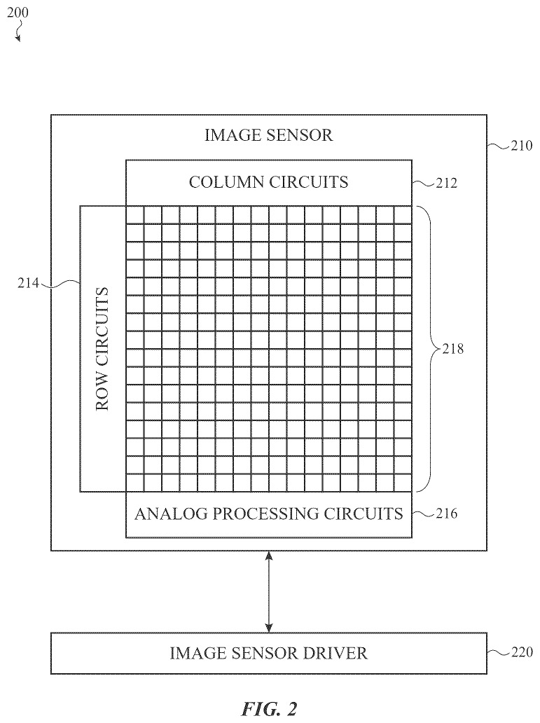

FIG. 2 shows an example image sensing device 200, according to certain aspects of the present disclosure. In one or more embodiments, image sensing device 200 supports one or more aspects of an image sensor using a metasurface routing layer, as further described herein. The image sensing device 200 includes an image sensor 210 and image sensor driver 220 coupled with the image sensor 210.

The image sensor 210 includes an array of pixels 218 that includes an array of image sensor pixels, at least some of which are covered by a corresponding portion of a metasurface routing layer, as further described herein. The image sensor 210 further includes column circuits 212 and row circuits 214 used to selectively access and readout each image sensor pixel in the array of pixels 218 during integration, readout, and reset operations during a given image frame. Analog processing circuits 216 include one or more amplifiers and analog-to-digital converters (ADCs). The one or more amplifiers are used to read out charge collected from photodiodes of pixels of the array of pixels 218. The ADCs convert the analog signal associated with the collected charge to a digital signal indicating a value of the charge. Analog processing circuits 216 may include additional circuits such as gain control circuits (e.g., an automatic gain control (AGC) circuit).

Image sensor driver 220 includes circuits to supply signals to control various operations of the image sensor 210. Image sensor driver 220 can drive column circuits 212 and row circuits 214 during integration, readout, and reset operations of the image sensor 210. During operation of the image sensing device 200, the image sensor 210 may be operated to capture a series of image frames.

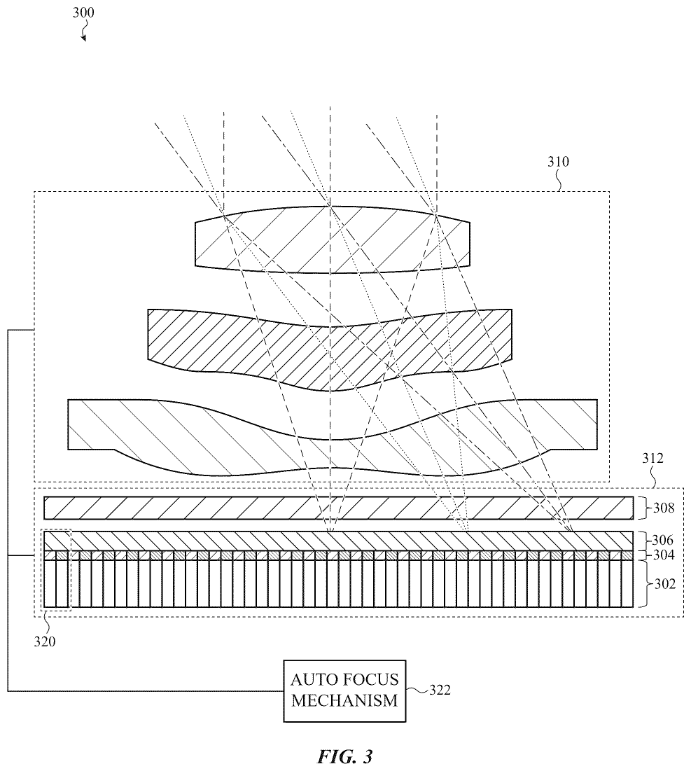

FIG. 3 shows a cross-section of an example image capture device 300, according to certain aspects of the present disclosure. In one or more embodiments, image capture device 300 supports one or more aspects of an image sensor using a metasurface routing layer, as further described herein. In some embodiments, the image capture device 300 may illustrate or be a portion of one or more of the first camera 102, the second camera 104, or the third camera 106, or the array of pixels 218.

The image capture device 300 includes an image sensor 312. The image sensor 312 includes an array of pixels 302, which may be referred to as image sensor pixels, that includes a pair of pixels 320. A color filter layer 304 is disposed on the array of pixels 302. In some embodiments, the color filter layer 304 may include instances of red, blue, and green color filter regions, each color filter region disposed over one or more of the pixels of the array of pixels 302. The color filter regions of the color filter layer 304 may be arranged according to a Bayer color filter mosaic, as further described herein. A metasurface layer 306 is disposed over the color filter layer 304. As further described herein, the metasurface layer 306 may include metasurface regions that pass light of a certain color to a corresponding color filter. The metasurface regions may overlap, and define effective resolutions of different sizes for different pixels. Although not shown, one or more additional layers may be formed between the array of pixels 302 and the color filter layer 304. Additionally, or alternatively, one or more layers may be formed between the color filter layer 304 and the metasurface layer 306.

In some embodiments, the image capture device 300 may include an infrared filter 308 that filters out infrared light before incident light reaches the metasurface layer 306. In some embodiments, the image capture device 300 may include imaging lenses 310. Although three imaging lenses are illustrated, any suitable quantity of lenses may be used with the image capture device 300. In some embodiments, for example in connection with an AF procedure, the position of one or more of the imaging lenses 310 may be adjusted, in particular a distance between the imaging lenses and the image sensor 312.

The imaging lenses 310 may be adjustable with respect to the image sensor 312, to focus an image of a scene on the image sensor 312. In some embodiments, the imaging lenses 310 may be moved with respect to the image sensor 312 (e.g., moved to change a distance between the imaging lenses 310 and the image sensor 312, moved to change an angle between a plane of imaging lenses 310 and a plane of the image sensor 312, and so on). In other embodiments, the image sensor 312 may be moved with respect to the imaging lenses 310.

In some embodiments, the autofocus mechanism 322 may include (or the functions of the autofocus mechanism 322 may be provided by) a processor in combination with a voice coil, piezoelectric element, or other actuator mechanism that moves the imaging lenses 310 or image sensor 312. The autofocus mechanism 322 may receive signals from the image sensor 312 and, in response to the signals, adjust a focus setting of the image capture device 300. In some embodiments, the signals may include PDAF information. The PDAF information may include horizontal phase detection signals, vertical phase detection signals, and/or other phase detection signals. In response to the PDAF information (e.g., in response to an out-of-focus condition identified from the PDAF information), the autofocus mechanism 322 calculates a focus setting. To calculate the focus setting (including a focus position), the image sensor 312 may evaluate signals from groups of PDAF pixels, also referred to as “focus pixels” (e.g., pairs of 1×2 pixels with different angular sensitivity, or groups of 2×2 pixels each having different angular sensitivity) to determine how similar these signals are, and thereby determine which regions of the scene are in or out of focus. Collectively, information from the focus pixels across the image sensor may be used to determine a target focus setting. The autofocus mechanism 322 may then adjust the focus setting of the image capture device 300 by, for example, adjusting a relationship between the image sensor 312 (or plurality of pixels) and the imaging lenses 310 (e.g., by adjusting a physical position of the imaging lenses 310 or image sensor 312). Additionally, or alternatively, the processor of the autofocus mechanism 322 may use digital image processing techniques to adjust the values output by the pixels and/or photodetectors of the image sensor 312. The values may be adjusted to digitally improve, or otherwise alter, the focus of an image of a scene. In some embodiments, the autofocus mechanism 322 may be used to provide only mechanical, or only digital, focus adjustments.

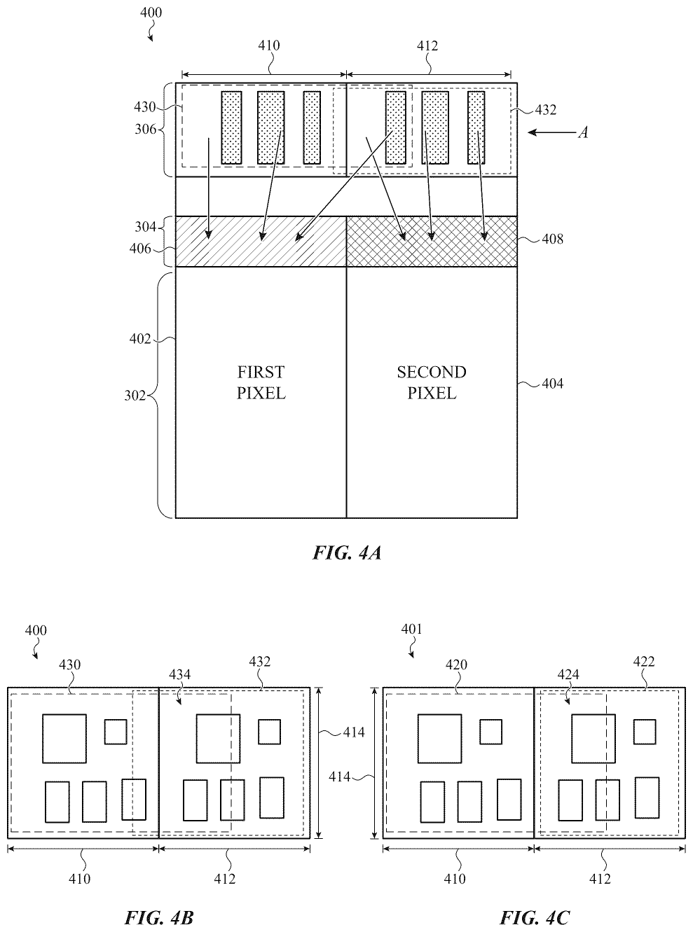

FIG. 4A shows a side view of a pair of pixels 400, according to certain aspects of the present disclosure. In one or more embodiments, the pair of pixels 400 supports one or more aspects of an image sensor using a metasurface routing layer, as further described herein. In some embodiments, the pair of pixels 400 may illustrate or be a portion of one or more of the array of pixels 218 or the image capture device 300, such as the pair of pixels 320.

The pair of pixels 400 include a first pixel 402 and a second pixel 404 from the array of pixels 302. Each pixel includes a corresponding photodiode, and may also include additional circuitry (e.g., transistors, capacitors, or the like) that can control operation of the pixel. The pair of pixels 400 further includes a first color filter 406 of the color filter layer 304 positioned over the first pixel 402 and a second color filter 408 positioned over the second pixel 404 of the color filter layer 304. The first color filter 406 may selectively pass for a first color, and the second color filter 408 may selectively pass light of a second color. The pair of pixels 400 further includes a metasurface layer 306 over the color filter layer 304.

The metasurface layer 306 has a first metasurface region 430 and a second metasurface region 432 of a metasurface layer 306. The first metasurface region 430 is configured to direct light of the first color (e.g., the same color passed by the first color filter 406) to the first pixel 402 and thereby defines a first effective resolution for the first pixel 402. As illustrated, the first metasurface region 430 may direct light of the first color to the first color filter 406 and the first pixel 402 from both from a portion of the metasurface layer 306 that is positioned above the first color filter 406 (and the first pixel 402) and from another portion of the metasurface layer 306 that is above the second color filter 408 (and the second pixel 404). Similarly, the second metasurface region 432 is configured to direct light of the second color (e.g., the same color passed by the second color filter 408) to the first pixel 402 and thereby defines a second effective resolution for the second pixel 404. The second metasurface region 432 may direct light of the second color to the second color filter 408 and second pixel 404 both from a portion of the metasurface layer 306 that is positioned above the second color filter 408 (and the second pixel 404) and from another portion of the metasurface layer 306 that is above the first color filter 406 (and the first pixel 402). In this way, light incident on certain portions of metasurface layer 306 positioned above the first pixel 402 may be routed to either the first pixel 402 or the second pixel 404, depending on its wavelength.

FIG. 4B shows a top view of the example pair of pixels 400, according to certain aspects of the present disclosure. The first pixel 402 has a first area of a width 410 and height 414. The second pixel 404 has a second area of a width 412 and height 414. The first metasurface region 430 includes the area of the metasurface layer over the first pixel 402 as well as a portion of the area of the metasurface layer over the second pixel 404. The second metasurface region 432 includes the area of the metasurface layer over the second pixel 404 as well as a portion of the metasurface layer over the area of the first pixel 402. In FIG. 4B, each of the metasurfaces may at least partially overlap two pixels (e.g., the first pixel 402 and the second pixel 404), but may have different levels of overlap to define different effective resolutions.

FIG. 4C shows a top view of another example pair of pixels 401, according to certain aspects of the present disclosure. The pair of pixels 401 may be similar to the pair of pixels 400, but having different metasurface regions, and thus defining different effective resolutions, for the first pixel 402 and the second pixel 404. The first metasurface region 420 includes the area of the metasurface layer over the first pixel 402 as well as a portion of the area of the metasurface layer over the second pixel 404. The second metasurface region 422 includes the area of the metasurface layer over the second pixel 404. However, as a difference from the pair of pixels 400, second metasurface region 422 for the pair of pixels 401 does not include a portion of the first metasurface region 420. In FIG. 4C, one of the metasurface regions (e.g., first metasurface region 420) may at least partially overlap two pixels (e.g., the first pixel 402 and the second pixel 404), while the other metasurface region (e.g., second metasurface region 422) overlaps a single pixel, but does not overlap an adjacent pixel.

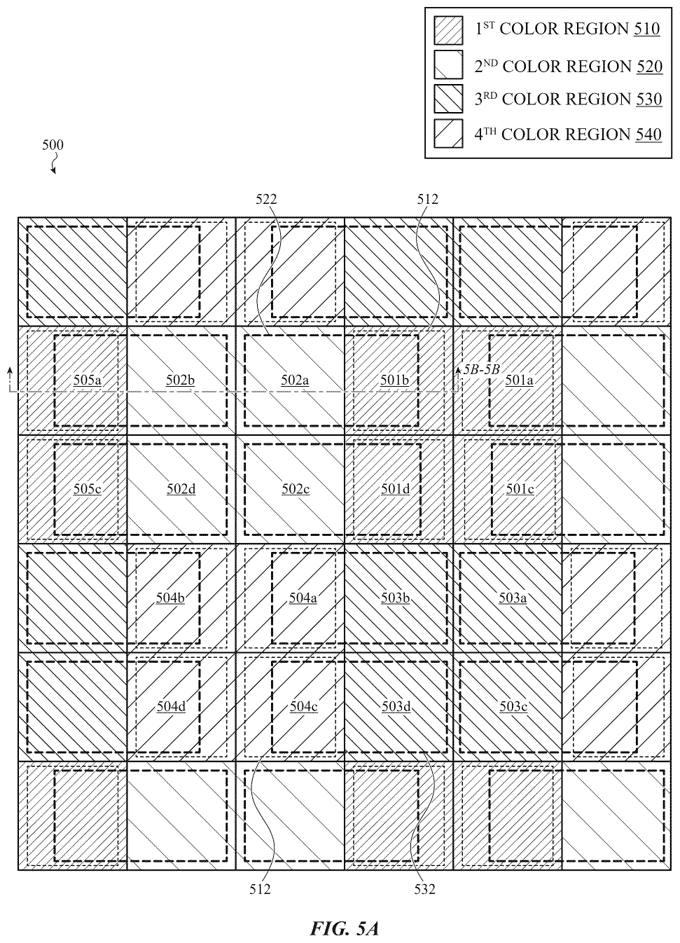

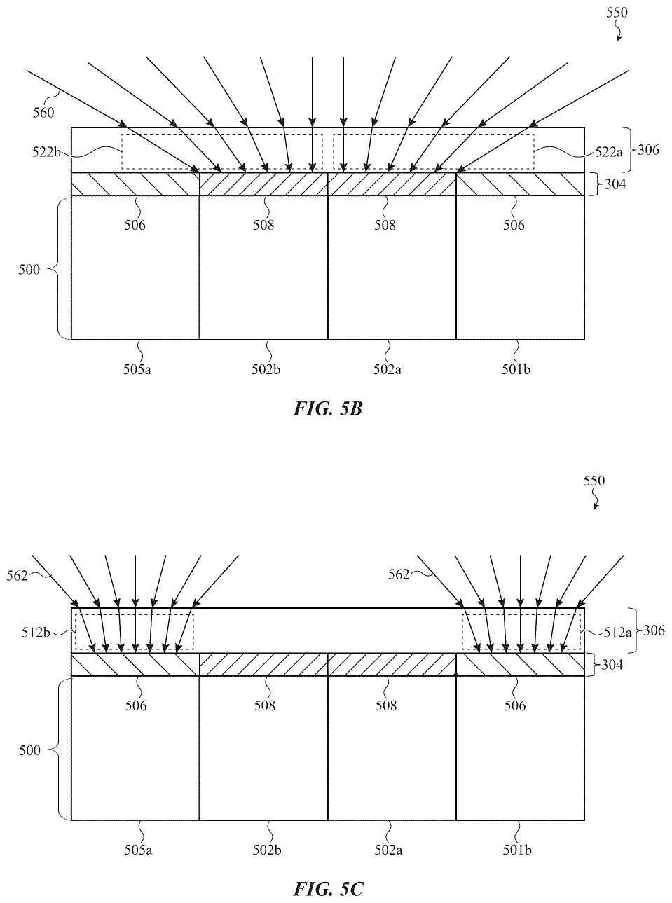

FIG. 5A shows a top view of an array of pixels 500, according to certain aspects of the present disclosure. In one or more embodiments, the array of pixels 500 supports one or more aspects of an image sensor using a metasurface routing layer, as further described herein. In some embodiments, the array of pixels 500 may illustrate or be a portion of one or more of the array of pixels 218 or the image capture device 300.

A color filter layer (as described with reference to any of FIGS. 5A-9) has a first set of first color regions for a first color (e.g., green), a second set of second color regions for a second color (e.g., blue), a third set of third color regions for a third color (e.g., red), and a fourth set of fourth color regions for the first color (e.g., green). Each color region includes a 2×2 array of color filters of a single color positioned over a corresponding set of 2×2 pixels. The sets of color regions are repeated across an image sensor. In particular, an instance of the first color region, an instance of the second color region, an instance of the third color region, and an instance of the fourth color region are each repeated as a group across the image sensor.

A color filter layer may be positioned over the array of pixels 500, the color filter array having a first color region 510 of the first set of first color regions associated with light of the first color, a second color region 520 of the second set of second color regions associated with light of the second color, a third color region 530 of the third set of third color regions associated with light of the third color (e.g., red), and a fourth color region 540 of the fourth set of fourth color regions associated with light of the first color.

The first color region 510 is positioned over a set of four pixels arranged in a 2×2 array, including a pixel 501a, a pixel 501b, a pixel 501c, and a pixel 501d. The second color region 520 is positioned over a set of four pixels arranged in a 2×2 array, including a pixel 502a, a pixel 502b, a pixel 502c, and a pixel 502d. The third color region 530 is positioned over a set of four pixels arranged in a 2×2 array, including a pixel 503a, a pixel 503b, a pixel 503c, and a pixel 503d. The fourth color region 540 is positioned over a set of four pixels arranged in a 2×2 array, including a pixel 504a, a pixel 504b, a pixel 504c, and a pixel 504d. Also labeled in FIG. 5A are two pixels (pixel 505a, pixel 505c) of another instance of a first color region the first set of color regions.

For the metasurface routing layer, each pixel associated with the first color (e.g., green) may have a first metasurface region 512 that defines a first effective resolution for the pixel. The first metasurface region 512 may be associated with the first color region 510 or the fourth color region 540.

Each pixel associated with the second color (e.g., blue) may have a second metasurface region 522 that defines a second effective resolution for the pixel. The second metasurface region 522 may be associated with the second color region 520, and at least partially overlap the first metasurface region 512 associated with an immediately adjacent pixel. For example, the first metasurface region 512 that passes (directs) light of the first color to the pixel 501b at least partially overlaps the second metasurface region 522 that passes (directs) light of the second color to the pixel 502a. As another example, the first metasurface region 512 that passes (directs) light of the first color to the pixel 501d at least partially overlaps the second metasurface region 522 that passes (directs) light of the second color to the pixel 502c.

Similarly, each pixel associated with the third color (e.g., red) may have a third metasurface region 532 that defines a third effective resolution for the pixel. The third metasurface region 532 may be associated with the third color region 530, and at least partially overlap the first metasurface region 512 associated with an immediately adjacent pixel. For example, the first metasurface region 512 that passes (directs) light of the first color to the pixel 504a at least partially overlaps the third metasurface region 532 that passes (directs) light of the third color to the pixel 503b. As another example, the first metasurface region 512 that passes (directs) light of the first color to the pixel 504c at least partially overlaps the third metasurface region 532 that passes (directs) light of the third color to the pixel 503d.

In one or more embodiments, the second effective resolution is larger than the first effective resolution. In some embodiments, the third effective resolution is larger than the fourth effective resolution. In some embodiments, the first effective resolution is the same as the fourth effective resolution. In some embodiments, the second effective resolution is the same as the third effective resolution. In other embodiments, the second effective resolution may be larger than or smaller than the third effective resolution.

As shown, for the array of pixels 500, each pair of adjacent pixels are generally horizontally oriented. As such, a second metasurface region 522 is generally wider than tall, providing a generally horizontally-oriented resolution for the second effective resolution. Similarly, a third metasurface region 532 is also generally wider than tall, providing a generally horizontally-oriented resolution for the third effective resolution. Adjacent pixels within a given color region may have corresponding metasurface regions that provide different angular responses, such that differences in the signals generated by the pairs is indicative of whether light received by the pair of pixels is in focus. For example, the metasurface region corresponding to a first pixel (e.g., pixel 502a) may be more sensitive to light incident from the right (e.g., and thereby has a first angular sensitivity in a horizontal direction) and the metasurface region corresponding to a second pixel (e.g., pixel 502b) may be more sensitive to light incident form the left (e.g., and thereby has a second angular sensitivity in the horizontal direction that is different than the first angular sensitivity). Accordingly, the pair of pixels form a pair of horizontally-oriented focus pixels. Horizontally-oriented adjacent pixels may be used to detect horizontally-oriented edges (e.g., for purposes of performing autofocus operations).

FIG. 5B shows a cross-sectional side view of an image sensor 550 that includes the array of pixels 500 of FIG. 5A (taken along line 5B-5B to illustrate pixel 501b, pixel 502a, pixel 502b, and pixel 505a). FIG. 5B depicts how light of the second color is routed to pixel 502a and pixel 502b with different angular sensitivity. As shown in FIG. 5B, a color filter layer 304 and a metasurface layer 306 are each disposed over the array of pixels 500. The color filter layer 304 includes instances of a first color filter 506 configured to pass light of the first color and thereby define corresponding instances of the first color region 510, and instances of a second color filter 508 configured to pass light of the second color and thereby define corresponding instances of the second color region 520. Accordingly, instances of the first color filter 506 are positioned over pixel 501b and pixel 505a and instances of the second color filter 508 are positioned over pixel 502a and pixel 502b.

The metasurface layer 306 includes first and second instances of the second metasurface region 522 (labeled as 522a and 522b in FIG. 5B) that correspond to pixel 502a and pixel 502b, respectively. Light of the first wavelength is depicted in FIG. 5B using arrows 560. As shown in FIG. 5B, the first instance 522a of the second metasurface region 522 selectively routes light that is received from the right toward the pixel 502a. Conversely, the second instance 522b of the second metasurface region 522 selectively routes light that is received from the left toward the pixel 502b. Accordingly, the pair of pixel 502a and pixel 502b may form a pair of horizontally-oriented focus pixels.

The pixel 502a and pixel 502b are each considered to have “asymmetric” angular sensitivity, as they preferentially receive light from one side of the imaged scene. Each of these pixels may exhibit a similar angular response as if the half of the pixel was shielded (e.g., using a metal shield, such that half of the light incident on the pixel is blocked before reaching the photodiode) or as if the pixel were placed under half of a 2×1 OCL (e.g., such that the pixel receives light from one half, such as the left half or the right half, or the OCL). Because the instances 522a and 522b of the second metasurface region 522 are not limited to the footprint of their respective pixels 502a, 502b, these pixels may have greater QE as compared to a metal shield or OCL-based design. It should be appreciated that, in some instances, the metasurface region corresponding to a given pixel may be configured such that the pixel operates as if the pixel were placed under a quarter of a 2×2 OCL (e.g., such that the pixel receives light from a corresponding quarter of the OCL). In these instances, a group of four pixels (e.g., pixel 502a, pixel 502b, pixel 502c, and pixel 502d) may collectively act as a focus pixel group to detect both vertically-oriented edges and horizontally-oriented edges (e.g., for purposes of performing autofocus operations).

Other pixels of the pixel array 500 may not have asymmetric angular sensitivity, and instead may receive light at a range of angles that is centered on an optical axis of the image sensor. In these instances, the pixel is considered to have “symmetric” angular sensitivity and may operate as though a single lxi OCL is positioned over that pixel. For example, FIG. 5C shows an example of the image sensor 550 of FIG. 5B routing light of the first wavelength (represented by arrows 562) to pixel 501b and pixel 505a. Specifically, the metasurface layer 306 includes first and second instances of the first metasurface region 512 (labeled as 512a and 512b in FIG. 5C) that correspond to pixel 501b and pixel 505a, respectively. In these instances, the first instance 512a of the first metasurface region 512 symmetrically routes light to pixel 501b, and the second instance 512b of the first metasurface region 512 symmetrically routes light to pixel 505a.

In some variations, the pixels associated with the second color region 520 may form pairs of horizontally-oriented focus pixels. In these instances, the pair of pixels 502a and 502b may form a first pair of horizontally-oriented focus pixels and the pair of pixels 502c and 502d may similarly form a second pair of horizontally-oriented focus pixels. Additionally or alternatively, the pixels associated with the third color region 530 may form pairs of horizontally-oriented focus pixels. In these instances, the pair of pixels 503a and 503b may form a first pair of horizontally-oriented focus pixels and the pair of pixels 503c and 503d may similarly form a second pair of horizontally-oriented focus pixels.

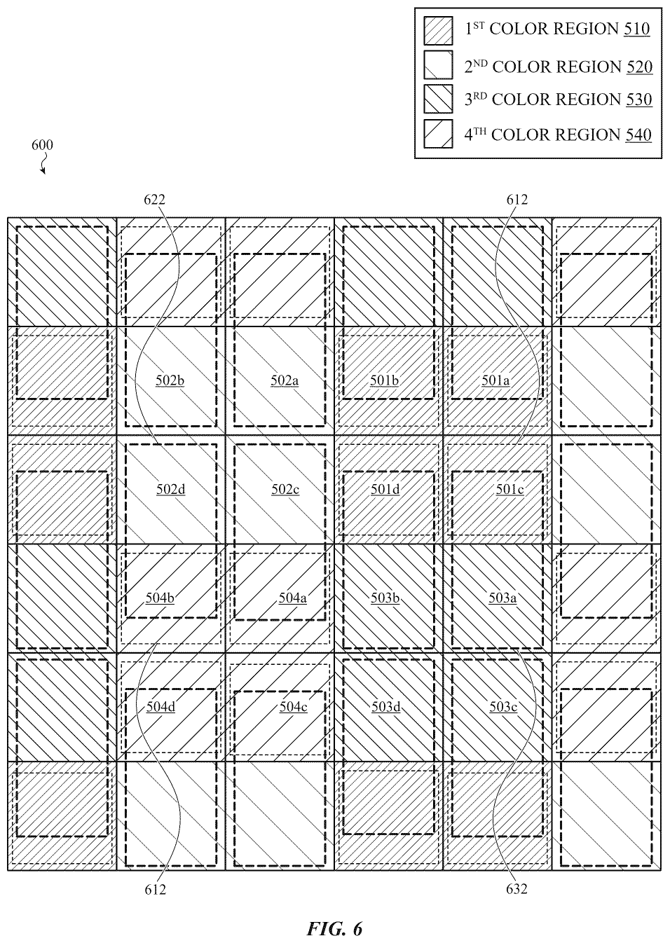

FIG. 6 shows a top view of an array of pixels 600, according to certain aspects of the present disclosure. Where the array of pixels 500 generally relate to an embodiment where each pair of adjacent pixels are generally horizontally oriented, the array of pixels 600 generally relate to an embodiment where each pair of adjacent pixels are generally vertically oriented.

Similar description of pixels and color regions of the array of pixels 500 that applies to the array of pixels 600 is omitted for purposes of clarity.

For the metasurface routing layer, each pixel associated with the first color (e.g., green) may have a first metasurface region 612 that defines a first effective resolution for the pixel. The first metasurface region 612 may be associated with the first color region 510 or the fourth color region 540.

Each pixel associated with the second color (e.g., blue) may have a second metasurface region 622 that defines a second effective resolution for the pixel. The second metasurface region 622 may be associated with the second color region 520, and at least partially overlap the first metasurface region 612 associated with an immediately adjacent pixel. For example, the first metasurface region 612 that passes (directs) light of the first color to the pixel 504b at least partially overlaps the second metasurface region 622 that passes (directs) light of the second color to the pixel 502d. As another example, the first metasurface region 612 that passes (directs) light of the first color to the pixel 504a at least partially overlaps the second metasurface region 522 that passes (directs) light of the second color to the pixel 502c.

Similarly, each pixel associated with the third color (e.g., red) may have a third metasurface region 632 that defines a third effective resolution for the pixel. The third metasurface region 632 may be associated with the third color region 530, and at least partially overlap the first metasurface region 612 associated with an immediately adjacent pixel. For example, the first metasurface region 612 that passes (directs) light of the first color to the pixel 501c at least partially overlaps the third metasurface region 632 that passes (directs) light of the third color to the pixel 503a. As another example, the first metasurface region 612 that passes (directs) light of the first color to the pixel 501d at least partially overlaps the third metasurface region 632 that passes (directs) light of the third color to the pixel 503b.

In one or more embodiments, the second effective resolution is larger than the first effective resolution. In some embodiments, the third effective resolution is larger than the fourth effective resolution. In some embodiments, the first effective resolution is the same as the fourth effective resolution. In some embodiments, the second effective resolution is the same as the third effective resolution. In other embodiments, the second effective resolution may be larger than or smaller than the third effective resolution.

As shown, for the array of pixels 600, each pair of adjacent pixels associated with the second color region 520 and the third color region 530 are generally vertically oriented. As such, a second metasurface region 622 is generally taller than wide, providing a generally vertically-oriented resolution for the second effective resolution. Similarly, a third metasurface region 632 is also generally taller than wide, providing a generally vertically-oriented resolution for the third effective resolution. Adjacent pixels within a given color region may have corresponding metasurface regions that provide different angular responses in a vertical direction. For example, the metasurface region corresponding to a first pixel (e.g., pixel 502a) may be more sensitive to light incident from the top (e.g., and thereby has a first angular sensitivity in a vertical direction) and the metasurface region corresponding to a second pixel (e.g., pixel 502c) may be more sensitive to light incident form the bottom (e.g., and thereby has a second angular sensitivity in the vertical direction that is different than the first angular sensitivity). Accordingly, the pair of pixels form a pair of vertically-oriented focus pixels. Vertically-oriented adjacent pixels may be used to detect vertically-oriented edges (e.g., for purposes of performing autofocus operations).

In some variations, the pixels associated with the second color region 520 may form pairs of vertically-oriented focus pixels. In these instances, the pair of pixels 502a and 502c may form a first pair of vertically-oriented focus pixels and the pair of pixels 502b and 502d may similarly form a second pair of vertically-oriented focus pixels. Additionally or alternatively, the pixels associated with the third color region 530 may form pairs of vertically-oriented focus pixels. In these instances, the pair of pixels 503a and 503b may form a first pair of vertically-oriented focus pixels and the pair of pixels 503c and 503d may similarly form a second pair of vertically-oriented focus pixels.

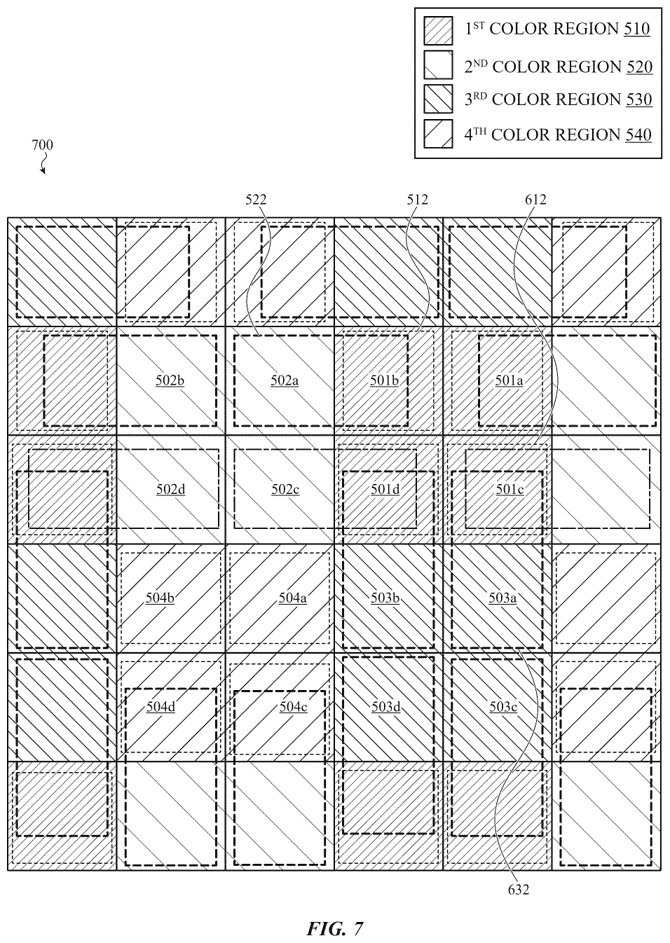

FIG. 7 shows a top view of an array of pixels 700, according to certain aspects of the present disclosure. Where the array of pixels 500 generally relate to an embodiment where each pair of adjacent pixels are generally horizontally oriented, and the array of pixels 600 generally relate to an embodiment where each pair of adjacent pixels are generally vertically oriented, the array of pixels 700 generally relate to an embodiment where some pairs of adjacent pixels are generally horizontally-oriented and some pairs of adjacent pixels are generally vertically-oriented.

Similar description of pixels, color regions, and metasurface region configurations of the array of pixels 500 and the array of pixels 600 that apply to the array of pixels 700 are omitted for purposes of clarity.

The array of pixels 500, the array of pixels 600, and the array of pixels 700 generally show configurations of a metasurface routing layer that provides a larger effective resolution for the second color light (e.g., blue) and the third color light (e.g., red) than for the first color light (e.g., green). In some cases, the signal-to-noise ratio (SNR) may be improved when performing white balancing. White balancing uses amplification to match signals, which introduces an increasing amount of noise for an increasing amount of gain used. However, using the described metasurface routing layers, less gain may be needed to match the red and/or blue signals to the green signals, such that the white-balancing procedure may not need as much gain, lowering SNR. A better SNR may improve image quality. Moreover, the configuration of the metasurface routing layer for the array of pixels 500 maintains a good resolution for the first color (e.g., green) and MTF performance. In particular, a high QE may be obtained while maintaining MTF performance over previous designs.

Adjacent pixels within a given color region may have corresponding metasurface regions that provide different angular responses, such that differences in the signals generated by the pairs is indicative of whether light received by the pair of pixels is in focus. Adjacent pixels associated with certain color regions may form pairs of vertically-oriented focus pixels, whereas adjacent pixels associated with other color regions may form pairs of horizontally-oriented focus pixels. The horizontally-oriented adjacent pixels may be used to detect horizontally-oriented edges, and the vertically-oriented adjacent pixels may be used to detect vertically-oriented edges (e.g., for purposes of autofocus).

For example, in the variation shown in FIG. 7, the pixels associated with the second color region 520 may form pairs of horizontally-oriented focus pixels and pixels associated with the third color region 530 may form pairs of vertically-oriented focus pixels. In these instances, the pair of pixels 502a and 502b may form a first pair of horizontally-oriented focus pixels and the pair of pixels 502c and 502d may similarly form a second pair of horizontally-oriented focus pixels. The pair of pixels 503a and 503b may form a first pair of vertically-oriented focus pixels and the pair of pixels 503c and 503d may similarly form a second pair of vertically-oriented focus pixels In these instances, the third metasurface region 632 associated with pixel 503b, the second metasurface region 522 associated with pixel 502c, and the first metasurface region 612 associated with pixel 501d may overlap over a portion of pixel 501d.

It should be appreciated that the distribution of horizontally-oriented focus pixels and vertically-oriented focus pixels may vary across the array of pixels 700. For example, in some variations the pixels associated with a first instance of the second color region 520 (such as depicted with respect to the pixels 502a-502d of FIG. 7) may be configured as pairs of horizontally-oriented focus pixels, whereas the pixels associated with a second instance of the second color region 520 (not shown) at a different location in the array of pixels 700 may be configured as pairs of vertically-oriented focus pixels. Similarly, the pixels associated with a first instance of the third color region 530 (such as depicted with respect to the pixels 503a-503d of FIG. 7) may be configured as pairs of vertically-oriented focus pixels, whereas the pixels associated with a second instance of the third color region 530 (not shown) may be configured as pairs of horizontally-oriented focus pixels.

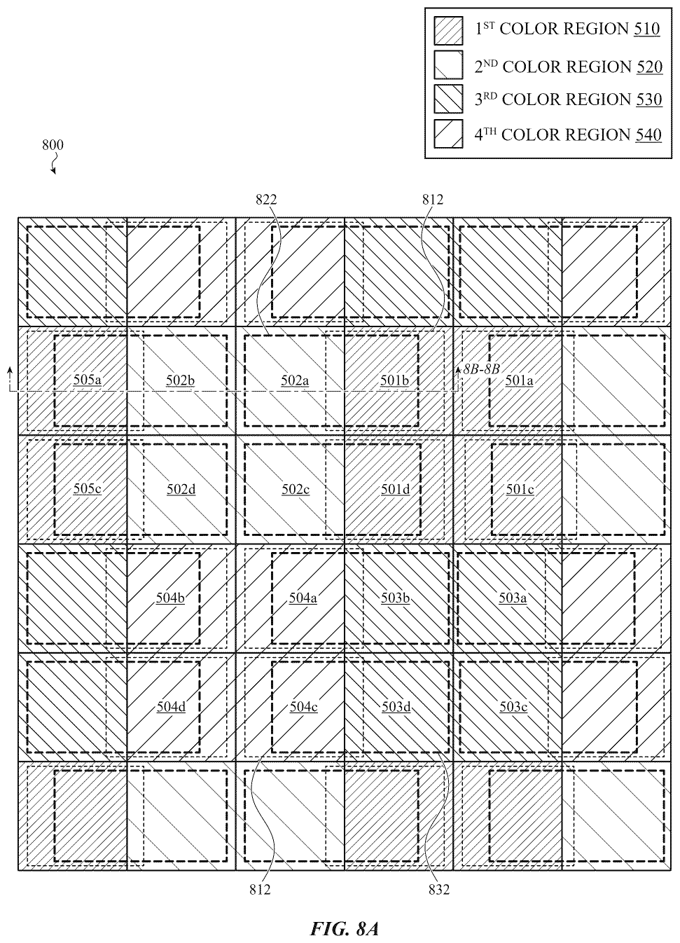

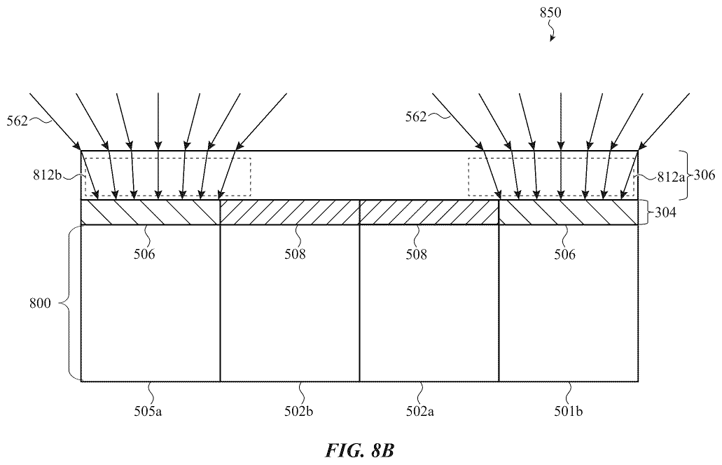

FIG. 8A shows a top view of an array of pixels 800, according to certain aspects of the present disclosure. In one or more embodiments, the array of pixels 800 supports one or more aspects of an image sensor using a metasurface routing layer, as further described herein. In some embodiments, the array of pixels 800 may illustrate or be a portion of one or more of the array of pixels 218, the image capture device 300, such as the pair of pixels 320, or the pair of pixels 401.

The array of pixels 800 generally show configurations of a metasurface routing layer that provides a larger effective resolution (thus increasing the QE) for the first color light (e.g., green) relative to the configurations of the metasurface routing layer discussed with reference to the array of pixels 500, the array of pixels 600, and the array of pixels 700. That is the first color light (e.g., green) has a metasurface routing layer that has a larger effective resolution, in addition to the second color light (e.g., blue) and the third color light (e.g., red).

Similar description of pixels and color regions of the array of pixels 500, the array of pixels 600, the array of pixels 700 that apply to the array of pixels 800 are omitted for purposes of clarity.

For the metasurface routing layer, each pixel associated with the first color (e.g., green) may have a first metasurface region 812 that defines a first effective resolution for the corresponding pixel. The first metasurface region 812 includes both a portion of the metasurface layer above the corresponding pixel and a portion of the metasurface layer above an immediately adjacent pixel. The metasurface layer above the immediately adjacent pixel may be a second metasurface region 822 (for a pixel of the second color region 520) or the third metasurface region 832 (for a pixel of the third color region 530).

The first metasurface region 812 may be associated with the first color region 510 or the fourth color region 540.

Each pixel (a pixel immediately adjacent a pixel of the first color region 510) associated with the second color (e.g., blue) may have a second metasurface region 822 that defines a second effective resolution for the pixel. The second metasurface region 822 may be associated with the second color region 520, and at least partially overlap the first metasurface region 812 associated with an immediately adjacent pixel, and vice versa. For example, the first metasurface region 812 that passes (directs) light of the first color to the pixel 501b at least partially overlaps the second metasurface region 822 that passes (directs) light of the second color to the pixel 502a. In addition, a majority of the area of the first metasurface region 812 is disposed over the pixel 501b, while a minority of the area of the first metasurface region 812 is disposed over the pixel 502a. Similarly, a majority of the area of the second metasurface region 822 is disposed over the pixel 502a, while a minority of the area of the second metasurface region 822 is disposed over the pixel 501b.

Similarly, each pixel (a pixel immediately adjacent a pixel of the fourth color region 540) associated with the third color (e.g., red) may have a third metasurface region 832 that defines a third effective resolution for the pixel. The third metasurface region 832 may be associated with the third color region 530, and at least partially overlap the first metasurface region 812 associated with an immediately adjacent pixel, and vice versa. For example, the first metasurface region 812 that passes (directs) light of the first color to the pixel 504c at least partially overlaps the third metasurface region 832 that passes (directs) light of the third color to the pixel 503d. In addition, a majority of the area of the first metasurface region 812 is disposed over the pixel 504c, while a minority of the area of the first metasurface region 812 is disposed over the pixel 503d. Similarly, a majority of the area of the third metasurface region 832 is disposed over the pixel 503d, while a minority of the area of the third metasurface region 832 is disposed over the pixel 504c.

Although each instance the first metasurface region 812 shown in FIG. 8A is positioned over multiple pixels, the pixel corresponding to the first metasurface regions 812 may still be configured to have a symmetric angular response. For example, FIG. 8B shows an example of the image sensor 850 that includes the array of pixels 800 of FIG. 8A (taken along line 8B-8B). The image sensor 850 may include a color filter array 304 and a metasurface layer 306 as described herein with respect to FIG. 5B. The image sensor 850 is shown in FIG. 8B routing light of the first wavelength (represented by arrows 562) to pixel 501b and pixel 505a. Specifically, the metasurface layer 306 includes first and second instances of the first metasurface region 812 (labeled as 812a and 812b in FIG. 5B) that correspond to pixel 501b and pixel 505a, respectively. In these instances, the first instance 812a of the first metasurface region 812 symmetrically routes light to pixel 501b, even though a portion of the first instance 812a of the first metasurface region 812 is positioned over pixel 502a. Similarly, the second instance 812b of the first metasurface region 812 symmetrically routes light to pixel 505a, even though a portion of the second instance 812b of the first metasurface region 812 is positioned over pixel 502b.

In one or more embodiments, the second effective resolution is larger than the first effective resolution. In some embodiments, the third effective resolution is larger than the fourth effective resolution. In some embodiments, the first effective resolution is the same as the fourth effective resolution. In some embodiments, the second effective resolution is the same as the third effective resolution. In other embodiments, the second effective resolution may be larger than or smaller than the third effective resolution.

As shown, for the array of pixels 800, each pair of adjacent pixels are generally horizontally oriented. As such, a second metasurface region 822 is generally wider than tall, providing a generally horizontally-oriented resolution for the second effective resolution. Similarly, a third metasurface region 832 is also generally wider than tall, providing a generally horizontally-oriented resolution for the third effective resolution.

Alternative arrangements and combinations, including pairs of adjacent pixels being generally vertically oriented (e.g., similar to the array of pixels 600), or pairs of adjacent pixels being generally a combination of generally horizontally-oriented and vertically-oriented (e.g., similar to the array of pixels 700).

The array of pixels 800 generally show configurations of a metasurface routing layer that can improve the sensitivity of the first color (e.g., green), for example relative to the second color (e.g., blue) or third color (e.g., red). However, such configuration may also reduce the resolution of the first color. Adjacent pixels associated with the second color region 520 and/or third color region 530 may be configured as pairs of focus pixels, such as described herein with respect to FIG. 5A. In some instances, pairs of pixels associated with the first color (e.g., the first color region 510 and the fourth color region 540) may also be configured to different angular responses, and thus may be configured as pairs of focus pixels. In other instances, however, the pixels associated with the first color may not be used as part of an autofocus operation as described herein.

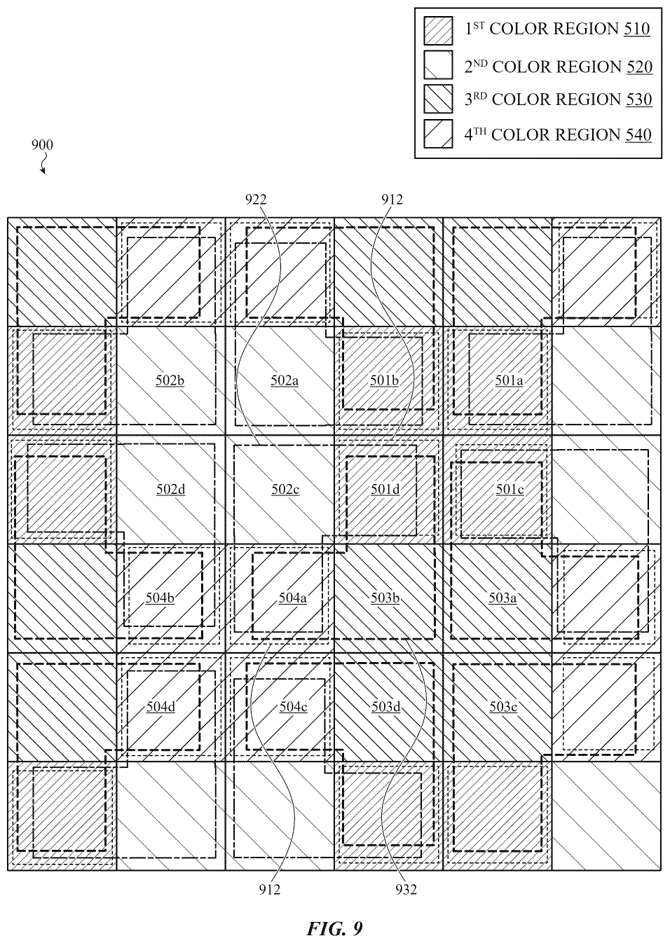

FIG. 9 shows a top view of an array of pixels 900, according to certain aspects of the present disclosure. In one or more embodiments, the array of pixels 900 supports one or more aspects of an image sensor using a metasurface routing layer, as further described herein. In some embodiments, the array of pixels 900 may illustrate or be a portion of one or more of the array of pixels 218, the image capture device 300, such as the pair of pixels 320, or the pair of pixels 400.

Similar description of pixels and color regions of the array of pixels 500, the array of pixels 600, the array of pixels 700, or the array of pixels 800 that applies to the array of pixels 900 is omitted for purposes of clarity.

For the metasurface routing layer, each pixel associated with the first color (e.g., green) may have a first metasurface region 912 that defines a first effective resolution for the pixel. The first metasurface region 912 may be associated with the first color region 510 or the fourth color region 540. For example, the pixel 501d and pixel 504a are each associated with a first metasurface region 912, the pixel 501d associated with the first color region 510 and the pixel 504a associated with the fourth color region 540.

Each pixel associated with the second color (e.g., blue) may have a second metasurface region 922 that defines a second effective resolution for the pixel. Each second metasurface region 922 may be associated with a corresponding pixel of the second color region 520, and may overlap with two metasurface regions associated with two immediately adjacent pixels. In particular, each second metasurface region 922 may be configured to at least partially overlap a first metasurface region 912 associated with a first immediately adjacent pixel of the first color region 510, and at least partially overlap a first metasurface region 912 associated with a second immediately adjacent pixel of the fourth color region 540. For example, the second metasurface region 922 that passes (directs) light of the second color to the pixel 502c at least partially overlaps both the first metasurface region 912 that passes (directs) light of the first color to the pixel 501d as well as the first metasurface region 912 that passes (directs) light of the first color to the pixel 504a. In this way, the second metasurface region 922 associated with pixel 502c may at least partially overlap the pixel 502c, the pixel 501d and the pixel 504a.

Similarly, each pixel associated with the third color (e.g., red) may have a third metasurface region 932 that defines a third effective resolution for the pixel. Each third metasurface region 932 may be associated with a corresponding pixel of the third color region 530, and may overlap with two metasurface regions associated with immediately adjacent pixels. In particular, each third metasurface region 932 may be configured at least partially overlap a first metasurface region 912 associated with a first immediately adjacent pixel of the first color region 510, and at least partially overlap a first metasurface region 912 associated with a second immediately adjacent pixel of the fourth color region 540. For example, the third metasurface region 932 that passes (directs) light of the third color to the pixel 503b at least partially overlaps both the first metasurface region 912 that passes (directs) light of the first color to the pixel 501d as well as the first metasurface region 912 that passes (directs) light of the first color to the pixel 504a. In this way, the third metasurface region 932 associated with pixel 503b may at least partially overlap the pixel 503b, the pixel 501d and the pixel 504a.

For the array of pixels 900, in some embodiments and as illustrated, the second metasurface region 922 may partially overlap with the third metasurface region 932. However, in other embodiments, the second metasurface region 922 may not necessarily overlap with the third metasurface region 932. For example, the second metasurface region 922 may overlap the first metasurface region 912 for the pixel 501d, and the third metasurface region 932 may overlap the first metasurface region 912 for the pixel 501d, but the second metasurface region 922 may not overlap the third metasurface region 932.

In one or more embodiments, the second effective resolution is larger than the first effective resolution. In some embodiments, the third effective resolution is larger than the fourth effective resolution. In some embodiments, the first effective resolution is the same as the fourth effective resolution. In some embodiments, the second effective resolution is the same as the third effective resolution. In other embodiments, the second effective resolution may be larger than or smaller than the third effective resolution.

The pixels associated with the second color region 520 may form a group of diagonally-oriented focus pixels, each of which is angularly sensitive to light along a different diagonal direction. For example, the pixel 502a may be angularly sensitive to light traveling along a first diagonal direction from the right and top, the pixel 502b may be angularly sensitive to light travelling along a second diagonal direction from the top and left, the pixel 502c may be angularly sensitive to light traveling along a third diagonal direction from the bottom and the right, and the pixel 502d may be angularly sensitive to light traveling along a fourth diagonal direction from the bottom and the left. In these instances, the signals from the pixels 502a-502d may be used to determine both horizontally-oriented edges and vertically-oriented edges. Additionally or alternatively, the pixels associated with the third color region 530 may form a group of diagonally-oriented focus pixels, each of which is angularly sensitive to light along a different diagonal direction. For example, the pixel 503a may be angularly sensitive to light traveling along a first diagonal direction from the right and top, the pixel 503b may be angularly sensitive to light travelling along a second diagonal direction from the top and left, the pixel 503c may be angularly sensitive to light traveling along a third diagonal direction from the bottom and the right, and the pixel 503d may be angularly sensitive to light traveling along a fourth diagonal direction from the bottom and the left.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

1. An image capture device, comprising:
an array of pixels, each pixel including a photodetector;
a color filter layer disposed over the array of pixels; and
a metasurface layer disposed over the color filter layer, wherein:
the array of pixels comprises a first pixel and a second pixel immediately adjacent to the first pixel;
the color filter layer comprises:
a first color region positioned over the first pixel and configured to pass light of a first color; and
a second color region positioned over the second pixel and configured to pass light of a second color;
the metasurface layer comprises:
a first metasurface region configured to pass light of the first color to the first color region and thereby define a first effective resolution for the first pixel; and
a second metasurface region configured to pass light of the second color to the second color region and thereby define a second effective resolution for the second pixel;
the second effective resolution is larger than the first effective resolution; and
the second metasurface region at least partially overlaps the first metasurface region.

2. The image capture device of claim 1, wherein:
the first color is green, the first effective resolution corresponds to an area of the first pixel; and
the second color is blue or red.

3. The image capture device of claim 1, wherein the color filter layer comprises:
the first color region;
the second color region immediately adjacent the first color region;
a third color region positioned over a third pixel, configured to pass light of a third color, and immediately adjacent the first color region; and
a fourth color region positioned over a fourth pixel, configured to pass light of the first color, and immediately adjacent both the second color region and the third color region.

4. The image capture device of claim 3, wherein the metasurface layer further comprises:
a third metasurface region configured to pass light of the third color to the third color region and thereby define a third effective resolution for the third pixel; and
a fourth metasurface region configured to pass light of the first color to the fourth color region and thereby define a fourth effective resolution for the fourth pixel, wherein:
the third effective resolution is larger than the fourth effective resolution; and
the third metasurface region at least partially overlaps the fourth metasurface region.

5. The image capture device of claim 4, wherein:
the first metasurface region is further configured to pass light of the third color to the third color region; and
the fourth metasurface region is further configured to pass light of the second color to the second color region.

6. The image capture device of claim 4, wherein:
the first color region is positioned over a first set of four pixels arranged in a first 2×2 array, the first set of four pixels including the first pixel;
the second color region is positioned over a second set of four pixels arranged in a second 2×2 array immediately adjacent the first set of four pixels, the second set of four pixels including the second pixel;
the third color region is positioned over a third set of four pixels arranged in a third 2×2 array immediately adjacent the first set of four pixels, including the third pixel; and
the fourth color region is positioned over a fourth set of four pixels arranged in a fourth 2×2 array immediately adjacent both the second set of four pixels and the third set of four pixels, the fourth set of four pixels including the fourth pixel.

7. The image capture device of claim 6, further comprising:
a fifth metasurface region configured to pass light of the first color to the first color region and thereby define a fifth effective resolution for a fifth pixel of the first set of four pixels arranged in the first 2×2 array; and
a sixth metasurface region configured to pass light of the second color to a fifth color region and thereby define a sixth effective resolution for a sixth pixel, the fifth color region over the fifth pixel and configured to pass light of the first color, wherein:
the fifth color region is immediately adjacent the first color region opposite the second color region; and
the fifth pixel is immediately adjacent the first pixel opposite the second pixel.

8. The image capture device of claim 6, wherein the metasurface layer further comprises:
a first plurality of metasurface regions associated with the second color region positioned over the second set of four pixels, wherein:
each of the first plurality of metasurface regions is configured to pass light of the second color to the second color region; and
each of the first plurality of metasurface regions at least partially overlaps at least two immediately adjacent metasurface regions for the first color; and
a second plurality of metasurface regions associated with the third color region positioned over the third set of four pixels, wherein:
each of the second plurality of metasurface regions is configured to pass light of the third color to the third color region; and
each of the second plurality of metasurface regions at least partially overlaps at least two immediately adjacent metasurface regions for the first color.

9. The image capture device of claim 3, wherein the metasurface layer further comprises:
a third metasurface region configured to pass light of the third color to the third color region and thereby define a third effective resolution for the third pixel; and
a fourth metasurface region configured to pass light of the first color to the fourth color region and thereby define a fourth effective resolution for the fourth pixel, wherein:
the third metasurface region at least partially overlaps the first metasurface region; and
the second metasurface region at least partially overlaps both the first metasurface region and the fourth metasurface region.

10. The image capture device of claim 1, wherein a material of a set of nanopillars of the metasurface layer comprises silicon nitride or titanium oxide.

11. The image capture device of claim 1, wherein a set of nanopillars of the metasurface layer comprise one or more of round nanopillars, square nanopillars, hexagonal nanopillars, rectangular nanopillars, cross-shaped nanopillars, or a polygon nanopillar with a hole extending therethrough.

12. An image capture device, comprising:
an array of pixels comprising a first set of pixels and a second set of pixels;
a color filter layer disposed over the array of pixels, the color filter layer comprising a first set of color regions corresponding to the first set of pixels and a second set of color regions corresponding to the second set of pixels; and
a metasurface layer disposed over the color filter layer, the metasurface layer comprising:
a first set of metasurface regions configured to pass light of a first color to the first set of color regions, each of the first set of metasurface regions defining a first effective resolution for a corresponding pixel of the first set of pixels; and
a second set of metasurface regions configured to pass light of a second color to the second set of color regions, each of the second set of metasurface regions defining a second effective resolution for a corresponding pixel of the second set of pixels, wherein:
the second effective resolution is larger than the first effective resolution; and
each metasurface region of the second set of metasurface regions at least partially overlaps a metasurface region of the first set of metasurface regions.

13. The image capture device of claim 12, wherein:
the array of pixels further comprises:
a third set of pixels; and
a fourth set of pixels;
the color filter layer further comprises:
a third set of color regions corresponding to the third set of pixels; and
a fourth set of color regions corresponding to the fourth set of pixels;
the metasurface layer further comprises:
a third set of metasurface regions configured to pass light of a third color to the third set of color regions, each of the third set of metasurface regions defining a third effective resolution for one of the third set of pixels; and
a fourth set of metasurface regions configured to pass light of the first color to the fourth set of color regions, each of the fourth set of metasurface regions defining a fourth effective resolution for one of the fourth set of pixels, wherein:
the third effective resolution is larger than the first effective resolution and the fourth effective resolution; and
each metasurface region of the third set of metasurface regions at least partially overlaps a metasurface region of the fourth set of metasurface regions.

14. The image capture device of claim 13, wherein:
the second set of metasurface regions are aligned in parallel with the third set of metasurface regions.

15. The image capture device of claim 13, wherein:
a first subset of the second set of metasurface regions are aligned in parallel with a first subset of the third set of metasurface regions and aligned perpendicular to a second subset of the third set of metasurface regions; and
a second subset of the second set of metasurface regions are aligned in parallel with the second subset of the third set of metasurface regions and aligned perpendicular to the first subset of the third set of metasurface regions.

16. The image capture device of claim 13, wherein:
each metasurface region of the second set of metasurface regions at least partially overlaps with a metasurface region of the first set of metasurface regions; and
each metasurface region of the third set of metasurface regions at least partially overlaps with a metasurface region of the fourth set of metasurface regions.

17. The image capture device of claim 13, wherein:
each metasurface region of the second set of metasurface regions overlaps with two metasurface regions of the first set of metasurface regions; and
each metasurface region of the third set of metasurface regions overlaps with two metasurface regions of the fourth set of metasurface regions.

18. The image capture device of claim 12, wherein:
the first color comprises green; and
the second color comprises blue or red.

19. A camera, comprising:
an image capture device, comprising:
an array of pixels;
a color filter layer disposed over the array of pixels;
a metasurface layer disposed over the color filter layer and the array of pixels, the metasurface layer comprising:
a first set of metasurface regions configured to pass light of a first color to a first set of color regions of the color filter layer, each metasurface region of the first set of metasurface regions defining a first effective resolution for a first set of pixels of the array of pixels; and
a second set of metasurface regions configured to pass light of a second color to a second set of color regions of the color filter layer, each metasurface region of the second set of metasurface regions defining a second effective resolution larger than the first effective resolution, and at least partially overlapping a metasurface region of the first set of metasurface regions;
a lens positioned over the image capture device and configured to direct light onto the image capture device;
an actuator controlling a position of the lens relative to the image capture device; and
a processor configured to:
acquire an image from the image capture device;
determine, based at least in part on the acquired image, a drive signal for the actuator according to an autofocus procedure; and
transmit the determined drive signal to the actuator.

20. The camera of claim 19, wherein the metasurface layer further comprises:
a third set of metasurface regions configured to pass light of a third color to the first set of color regions of the color filter layer, each metasurface region of the first set of metasurface regions defining a third effective resolution for a third set of pixels of the array of pixels; and
a fourth set of metasurface regions configured to pass light of the first color to a fourth set of color regions of the color filter layer, each metasurface region of the fourth set of metasurface regions defining a fourth effective resolution, wherein the third effective resolution is larger than the fourth effective resolution, and each metasurface region of the third set of metasurface regions at least partially overlaps a metasurface region of the third set of metasurface regions.
